(19) United States
(12) Patent Application Publication
(10) Pub. No.: US 2024/0255578 A1
(43) Pub. Date: Aug. 1, 2024

(54) ENERGY MANAGEMENT SYSTEMS

(71) Applicant: Enphase Energy, Inc., Petaluma, CA (US)

(72) Inventor: Zhen Alex HUANG, Pflugerville, TX (US)

(21) Appl. No.: 18/397,316

(22) Filed: Dec. 27, 2023

Related U.S. Application Data
(60) Provisional application No. 63/441,963, filed on Jan. 30, 2023.

(51) Int. Cl. G01R 31/3835; G01R 31/392; H02J 7/00; H02J 7/02

(52) U.S. Cl. CPC G01R 31/3835; G01R 31/392; H02J 7/0047; H02J 7/02

(57) ABSTRACT

An AC battery system configured for use with an energy management system is provided herein. For example, a controller can be configured to measure an initial voltage during a first predetermined state at a predetermined state-of-charge percentage, measure a subsequent voltage during a second predetermined state different from the first predetermined state, calculate a new hysteresis maximum polarization value based on a difference between the initial voltage and the subsequent voltage, and replace a previously stored hysteresis maximum polarization value with the new hysteresis maximum polarization value for performing at least one of a state-of-charge analysis or a state-of-health analysis.

### CROSS-REFERENCE TO RELATED APPLICATIONS

The present application claims the benefit of and priority to U.S. Provisional Application Ser. No. 63/441,963, filed on Jan. 30, 2023, the entire contents of which is incorporated herein by reference.

### BACKGROUND

### 1. Field of the Disclosure

Embodiments of the present disclosure generally relate to energy management systems, and, for example, to methods and apparatus for calculating maximum hysteresis polarization voltage in AC battery systems configured for use with energy management systems.

### 2. Description of the Related Art

Conventional AC battery systems configured for use with energy management systems are known. Hysteresis voltage plays a key role in accurately estimating state-of-charge (SOC) and state-of-health (SOH) of the AC battery systems. Typically, a hysteresis voltage value can be measured in a controlled environment (e.g., a lab) and programed into the AC battery system for a lifetime of the AC battery system. Such methods, however, do not consider a deviation in a battery pack of the AC battery system or cell to cell in a battery of the AC battery system. Further, over time the hysteresis voltage value can change as a battery of the AC battery system ages. Therefore, outdated hysteresis voltage values can introduce estimation errors to SOC and SOH over a life of the AC battery system.

In view of the foregoing, the inventor provides herein improved methods and apparatus for calculating maximum hysteresis polarization voltage in AC battery systems configured for use with energy management systems.

### SUMMARY

In accordance with some aspects of the present disclosure, an AC battery system configured for use with an energy management system comprises a controller configured to measure an initial voltage during a first predetermined state at a predetermined state-of-charge percentage, measure a subsequent voltage during a second predetermined state different from the first predetermined state, calculate a new hysteresis maximum polarization value based on a difference between the initial voltage and the subsequent voltage, and replace a previously stored hysteresis maximum polarization value with the new hysteresis maximum polarization value for performing at least one of a state-of-charge analysis or a state-of-health analysis.

In accordance with some aspects of the present disclosure, a method of operating an AC battery system configured for use with an energy management system comprises measuring an initial voltage during a first predetermined state at a predetermined state-of-charge percentage; measuring a subsequent voltage during a second predetermined state different from the first predetermined state; calculating a new hysteresis maximum polarization value based on a difference between the initial voltage and the subsequent voltage; and replacing a previously stored hysteresis maximum polarization value with the new hysteresis maximum polarization value for performing at least one of a state-of-charge analysis or a state-of-health analysis.

In accordance with some aspects of the present disclosure, a non-transitory computer readable storage medium has instructions stored thereon that when executed by a processor perform a method of operating an AC battery system configured for use with an energy management system. The method comprises measuring an initial voltage during a first predetermined state at a predetermined state-of-charge percentage; measuring a subsequent voltage during a second predetermined state different from the first predetermined state; calculating a new hysteresis maximum polarization value based on a difference between the initial voltage and the subsequent voltage; and replacing a previously stored hysteresis maximum polarization value with the new hysteresis maximum polarization value for performing at least one of a state-of-charge analysis or a state-of-health analysis.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only a typical embodiment of this disclosure and are therefore not to be considered limiting of its scope, for the disclosure may admit to other equally effective embodiments.

FIG. 1 is a block diagram of a system for power conversion, in accordance with at least some embodiments of the present disclosure;

FIG. 2 is a block diagram of an AC battery system configured for use with the system of FIG. 1, in accordance with at least some embodiments of the present disclosure;

FIG. 3 is a graph of voltage vs state-of-charge, in accordance with at least some embodiments of the present disclosure;

FIG. 4 is a graph of voltage vs state-of-charge, in accordance with at least some embodiments of the present disclosure; and

FIG. 5 is a flowchart of a method of operating AC battery systems, in accordance with at least some embodiments of the present disclosure.

### DETAILED DESCRIPTION

In accordance with the present disclosure, methods and apparatus for calculating maximum hysteresis polarization voltage in AC battery systems configured for use with energy management systems are disclosed herein. For example, an AC battery system configured for use with an energy management system comprises a controller configured to measure an initial voltage during a first predetermined state at a predetermined state-of-charge percentage, measure a subsequent voltage during a second predetermined state different from the first predetermined state, calculate a new hysteresis maximum polarization value based on a difference between the initial voltage and the subsequent voltage, and replace a previously stored hysteresis maximum polarization value with the new hysteresis maximum polarization value for performing at least one of a state-of-charge analysis or a state-of-health analysis. The methods and apparatus described herein take into consideration a deviation in a battery pack of the AC battery system or cell to cell in a battery of the AC battery system. Additionally, changes in hysteresis voltage values as a battery of the AC battery system ages can be accounted for, as a new hysteresis maximum polarization value can be dynamically calculated. Further, estimation errors that can be introduced to SOC and SOH over a life of the AC battery system due to outdated hysteresis voltage values are reduced, if not eliminated.

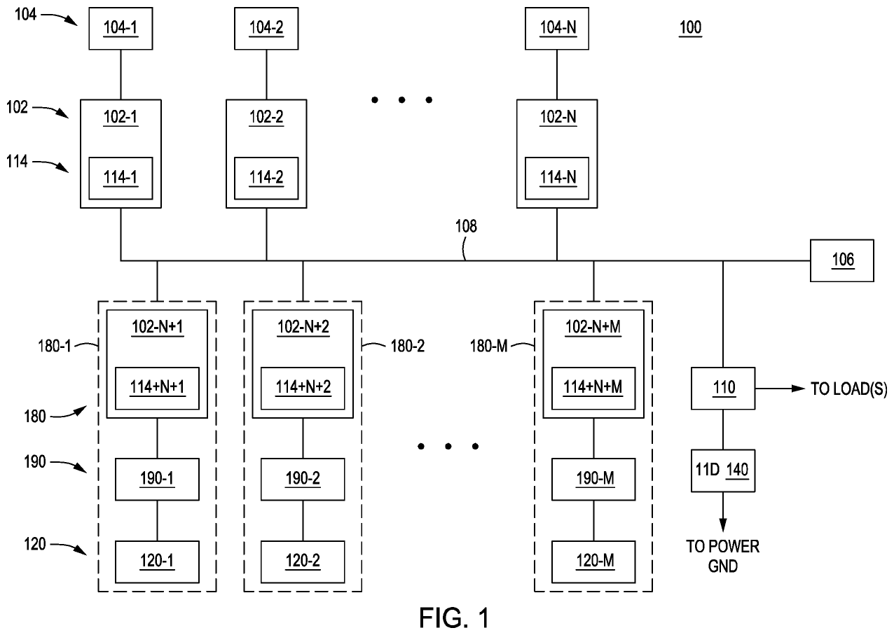

FIG. 1 is a block diagram of a system 100 (energy management system) for power conversion using one or more embodiments of the present disclosure. This diagram only portrays one variation of the myriad of possible system configurations and devices that may utilize the present disclosure.

The system 100 is a microgrid that can operate in both an islanded state and in a grid-connected state (i.e., when connected to another power grid (such as one or more other microgrids and/or a commercial power grid). The system 100 comprises a plurality of power converters 102-1, 102-2, . . . . 102-N, 102-N+1, and 102-N+M collectively referred to as power converters 102 (which also may be called power conditioners); a plurality of DC power sources 104-1, 104-2, . . . . 104-N, collectively referred to as power sources 104; a plurality of energy storage devices/delivery devices 120-1, 120-2, . . . 120-M collectively referred to as energy storage/delivery devices 120; a system controller 106; a plurality of BMUs 190-1, 190-2, . . . . 190-M (battery management units) collectively referred to as BMUs 190; a system controller 106; a bus 108; a load center 110; and an IID 140 (island interconnect device) (which may also be referred to as a microgrid interconnect device (MID)). In some embodiments, such as the embodiments described herein, the energy storage/delivery devices are rechargeable batteries (e.g., multi-C-rate collection of AC batteries) which may be referred to as batteries 120, although in other embodiments the energy storage/delivery devices may be any other suitable device for storing energy and providing the stored energy. Generally, each of the batteries 120 (e.g., each of the battery packs) comprises a plurality battery cells that are coupled in series, e.g., eight battery cells coupled in series to form a battery 120.

Each power converter 102-1, 102-2 . . . . 102-N is coupled to a DC power source 104-1, 104-2 . . . . 104-N, respectively, in a one-to-one correspondence, although in some other embodiments multiple DC power sources may be coupled to one or more of the power converters 102. The power converters 102-N+1, 102-N+2 . . . 102-N+M are respectively coupled to plurality of energy storage devices/delivery devices 120-1, 120-2 . . . 120-M via BMUs 190-1, 190-2 . . . 190-M to form AC batteries 180-1, 180-2 . . . 180-M, respectively. Each of the power converters 102-1, 102-2 . . . 102-N+M comprises a corresponding controller 114-1, 114-2 . . . 114-N+M (collectively referred to as the inverter controllers 114) for controlling operation of the power converters 102-1, 102-2 . . . 102-N+M.

In some embodiments, such as the embodiment described below, the DC power sources 104 are DC power sources and the power converters 102 are bidirectional inverters such that the power converters 102-1 . . . 102-N convert DC power from the DC power sources 104 to grid-compliant AC power that is coupled to the bus 108, and the power converters 102-N+1 . . . 102-N+M convert (during energy storage device discharge) DC power from the batteries 120 to grid-compliant AC power that is coupled to the bus 108 and also convert (during energy storage device charging) AC power from the bus 108 to DC output that is stored in the batteries 120 for subsequent use. The DC power sources 104 may be any suitable DC source, such as an output from a previous power conversion stage, a battery, a renewable energy source (e.g., a solar panel or photovoltaic (PV) module, a wind turbine, a hydroelectric system, or similar renewable energy source), or the like, for providing DC power. In other embodiments the power converters 102 may be other types of converters (such as DC-DC converters), and the bus 108 is a DC power bus.

The power converters 102 are coupled to the system controller 106 via the bus 108 (which also may be referred to as an AC line or a grid). The system controller 106 generally comprises a CPU coupled to each of support circuits and a memory that comprises a system control module for controlling some operational aspects of the system 100 and/or monitoring the system 100 (e.g., issuing certain command and control instructions to one or more of the power converters 102, collecting data related to the performance of the power converters 102, and the like). The system controller 106 is capable of communicating with the power converters 102 by wireless and/or wired communication (e.g., power line communication) for providing certain operative control and/or monitoring of the power converters 102.

In some embodiments, the system controller 106 may be a gateway that receives data (e.g., performance data) from the power converters 102 and communicates (e.g., via the Internet) the data and/or other information to a remote device or system, such as a master controller (not shown). Additionally or alternatively, the gateway may receive information from a remote device or system (not shown) and may communicate the information to the power converters 102 and/or use the information to generate control commands that are issued to the power converters 102.

The power converters 102 are coupled to the load center 110 via the bus 108, and the load center 110 is coupled to the power grid via the IID 140. When coupled to the power grid (e.g., a commercial grid or a larger microgrid) via the IID 140, the system 100 may be referred to as grid-connected; when disconnected from the power grid via the IID 140, the system 100 may be referred to as islanded. The IID 140 determines when to disconnect from/connect to the power grid (e.g., the IID 140 may detect a grid fluctuation, disturbance, outage or the like) and performs the disconnection/connection. Once disconnected from the power grid, the system 100 can continue to generate power as an intentional island, without imposing safety risks on any line workers that may be working on the grid, using the droop control techniques described herein. The IID 140 comprises a disconnect component (e.g., a disconnect relay) for physically disconnecting/connecting the system 100 from/to the power grid. In some embodiments, the IID 140 may additionally comprise an autoformer for coupling the system 100 to a split-phase load that may have a misbalance in it with some neutral current. In certain embodiments, the system controller 106 comprises the IID 140 or a portion of the IID 140.

The power converters 102 convert the DC power from the DC power sources 104 and discharging batteries 120 to grid-compliant AC power and couple the generated output power to the load center 110 via the bus 108. The power is then distributed to one or more loads (for example to one or more appliances) and/or to the power grid (when connected to the power grid). Additionally or alternatively, the generated energy may be stored for later use, for example using batteries, heated water, hydro pumping, H₂O-to-hydrogen conversion, or the like. Generally, the system 100 is coupled to the commercial power grid, although in some embodiments the system 100 is completely separate from the commercial grid and operates as an independent microgrid.

In some embodiments, the AC power generated by the power converters 102 is single-phase AC power. In other embodiments, the power converters 102 generate three-phase AC power.

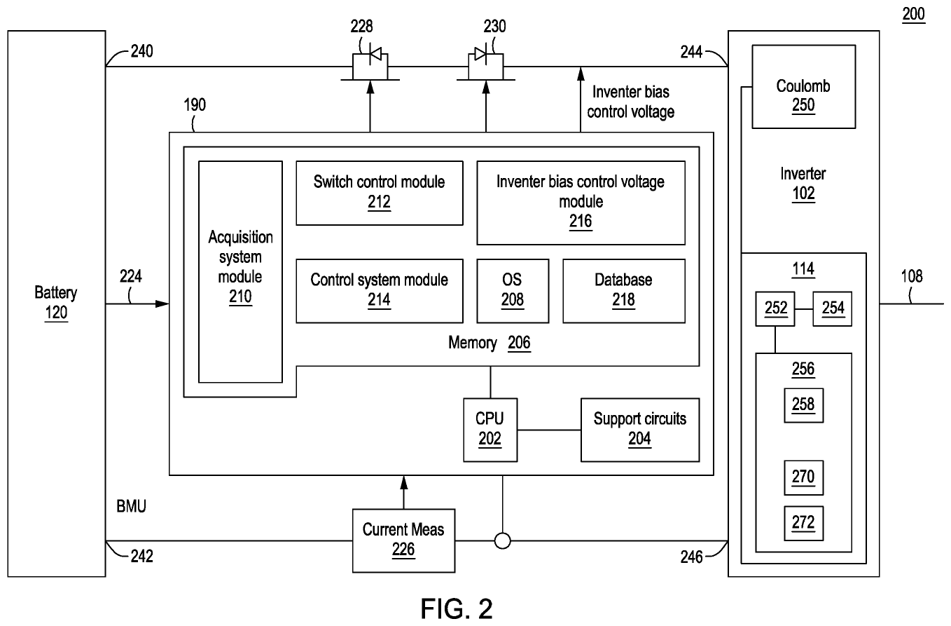

A storage system configured for use with an energy management system, such as the ENSEMBLE® energy management system available from ENPHASE®, is described herein. For example, FIG. 2 is a block diagram of an AC battery system 200 (e.g., a storage system) in accordance with one or more embodiments of the present disclosure.

The AC battery system 200 comprises a BMU 190 coupled to a battery 120 and a power converter 102. A pair of metal-oxide-semiconductor field-effect transistors (MOSFETs) switches—switches 228 and 230—are coupled in series between a first terminal 240 of the battery 120 and a first terminal of the inverter 144 such the body diode cathode terminal of the switch 228 is coupled to the first terminal 240 of the battery 120 and the body diode cathode terminal of the switch 230 is coupled to the first terminal 244 of the power converter 102. The gate terminals of the switches 228 and 230 are coupled to the BMU 190.

A second terminal 242 of the battery 120 is coupled to a second terminal 246 of the power converter 102 via a current measurement module 226 which measures the current flowing between the battery 120 and the power converter 102.

The BMU 190 is coupled to the current measurement module 226 for receiving information on the measured current, and also receives an input 224 from the battery 120 indicating the battery cell voltage and temperature. The BMU 190 is coupled to the gate terminals of each of the switches 228 and 230 for driving the switch 228 to control battery discharge and driving the switch 230 to control battery charge as described herein. The BMU 190 is also coupled across the first terminal 244 and the second terminal 246 for providing an inverter bias control voltage (which may also be referred to as a bias control voltage) to the inverter 102 as described further below.

The configuration of the body diodes of the switches 228 and 230 allows current to be blocked in one direction but not the other depending on state of each of the switches 228 and 230. When the switch 228 is active (i.e., on) while the switch 230 is inactive (i.e., off), battery discharge is enabled to allow current to flow from the battery 120 to the power converter 102 through the body diode of the switch 230. When the switch 228 is inactive while the switch 230 is active, battery charge is enabled to allow current flow from the power converter 102 to the battery 120 through the body diode of the switch 228. When both switches 228 and 230 are active, the system is in a normal mode where the battery 120 can be charged or discharged.

The BMU 190 comprises support circuits 204 and a memory 206 (e.g., non-transitory computer readable storage medium), each coupled to a CPU 202 (central processing unit). The CPU 202 may comprise one or more processors, microprocessors, microcontrollers and combinations thereof configured to execute non-transient software instructions to perform various tasks in accordance with embodiments of the present disclosure. The CPU 202 may additionally or alternatively include one or more application specific integrated circuits (ASICs). In some embodiments, the CPU 202 may be a microcontroller comprising internal memory for storing controller firmware that, when executed, provides the controller functionality described herein. The BMU 190 may be implemented using a general purpose computer that, when executing particular software, becomes a specific purpose computer for performing various embodiments of the present disclosure.

The support circuits 204 are well known circuits used to promote functionality of the CPU 202. Such circuits include, but are not limited to, a cache, power supplies, clock circuits, buses, input/output (I/O) circuits, and the like. The BMU 190 may be implemented using a general purpose computer that, when executing particular software, becomes a specific purpose computer for performing various embodiments of the present disclosure. In one or more embodiments, the CPU 202 may be a microcontroller comprising internal memory for storing controller firmware that, when executed, provides the controller functionality described herein.

The memory 206 may comprise random access memory, read only memory, removable disk memory, flash memory, and various combinations of these types of memory. The memory 206 is sometimes referred to as main memory and may, in part, be used as cache memory or buffer memory. The memory 206 generally stores the OS 208 (operating system), if necessary, of the inverter controller 114 that can be supported by the CPU capabilities. In some embodiments, the OS 208 may be one of a number of commercially available operating systems such as, but not limited to, LINUX, Real-Time Operating System (RTOS), and the like.

The memory 206 stores non-transient processor-executable instructions and/or data that may be executed by and/or used by the CPU 202 to perform, for example, one or more methods for discharge protection, as described in greater detail below. These processor-executable instructions may comprise firmware, software, and the like, or some combination thereof. The memory 206 stores various forms of application software, such as an acquisition system module 210, a switch control module 212, a control system module 214, and an inverter bias control module 216. The memory 206 additionally stores a database 218 for storing data related to the operation of the BMU 190 and/or the present disclosure, such as one or more thresholds, equations, formulas, curves, and/or algorithms for the control techniques described herein. In various embodiments, one or more of the acquisition system module 210, the switch control module 212, the control system module 214, the inverter bias control module 216, and the database 218, or portions thereof, are implemented in software, firmware, hardware, or a combination thereof.

The acquisition system module 210 obtains the cell voltage and temperature information from the battery 120 via the input 224, obtains the current measurements provided by the current measurement module 226, and provides the cell voltage, cell temperature, and measured current information to the control system module 214 for use as described herein.

The switch control module 212 drives the switches 228 and 230 as determined by the control system module 214. The control system module 214 provides various battery management functions, including protection functions (e.g., overcurrent (OC) protection, overtemperature (OT) protection, and hardware fault protection), metrology functions (e.g., averaging measured battery cell voltage and battery current over, for example, 100 ms to reject 50 and 60 Hz ripple), state of charge (SOC) analysis (e.g., coulomb gauge 250 for determining current flow and utilizing the current flow in estimating the battery SOC; synchronizing estimated SOC values to battery voltages (such as setting SOC to an upper bound, such as 100%, at maximum battery voltage; setting SOC to a lower bound, such as 0%, at a minimum battery voltage); turning off SOC if the power converter 102 never drives the battery 120 to these limits; and the like), balancing (e.g., autonomously balancing the charge across all cells of a battery to be equal, which may be done at the end of charge, at the end of discharge, or in some embodiments both at the end of charge and the end of discharge). By establishing upper and lower estimated SOC bounds based on battery end of charge and end of discharge, respectively, and tracking the current flow and cell voltage (i.e., battery voltage) between these events, the BMU 190 determines the estimated SOC.

The inverter controller 114 comprises support circuits 254 and a memory 256, each coupled to a CPU 252 (central processing unit). The CPU 252 may comprise one or more processors, microprocessors, microcontrollers and combinations thereof configured to execute non-transient software instructions to perform various tasks in accordance with embodiments of the present disclosure. The CPU 252 may additionally or alternatively include one or more application specific integrated circuits (ASICs). In some embodiments, the CPU 252 may be a microcontroller comprising internal memory for storing controller firmware that, when executed, provides the controller functionality herein. The inverter controller 114 may be implemented using a general purpose computer that, when executing particular software, becomes a specific purpose computer for performing various embodiments of the present disclosure.

The support circuits 254 are well known circuits used to promote functionality of the CPU 252. Such circuits include, but are not limited to, a cache, power supplies, clock circuits, buses, input/output (I/O) circuits, and the like. The inverter controller 114 may be implemented using a general purpose computer that, when executing particular software, becomes a specific purpose computer for performing various embodiments of the present disclosure. In one or more embodiments, the CPU 252 may be a microcontroller comprising internal memory for storing controller firmware that, when executed, provides the controller functionality described herein.

The memory 256 may comprise random access memory, read only memory, removable disk memory, flash memory, and various combinations of these types of memory. The memory 256 is sometimes referred to as main memory and may, in part, be used as cache memory or buffer memory. The memory 256 generally stores the OS 258 (operating system), if necessary, of the inverter controller 114 that can be supported by the CPU capabilities. In some embodiments, the OS 258 may be one of a number of commercially available operating systems such as, but not limited to, LINUX, Real-Time Operating System (RTOS), and the like.

The memory 256 stores non-transient processor-executable instructions and/or data that may be executed by and/or used by the CPU 252. These processor-executable instructions may comprise firmware, software, and the like, or some combination thereof. The memory 256 stores various forms of application software, such as a power conversion control module 270 for controlling the bidirectional power conversion, and a battery management control module 272.

The BMU 190 communicates with the system controller 106 to perform balancing of the batteries 120 (e.g., multi-C-rate collection of AC batteries) based on a time remaining before each of the batteries are depleted of charge, to perform droop control (semi-passive) which allows the batteries to run out of charge at substantially the same time, and perform control of the batteries to charge batteries having less time remaining before depletion using batteries having more time remaining before depletion, as described in greater detail below.

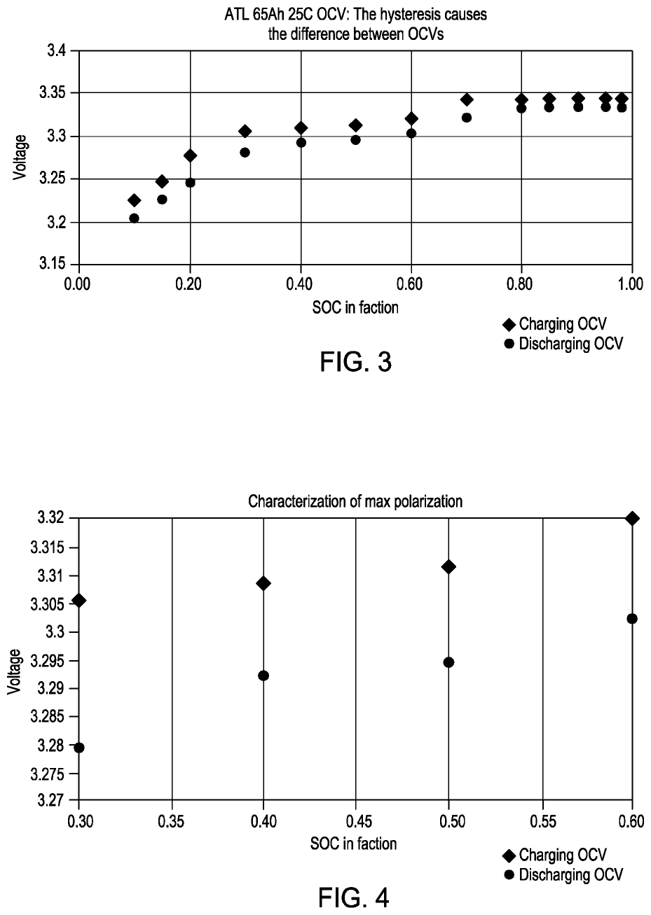

FIG. 3 is a graph of voltage vs state-of-charge, in accordance with at least some embodiments of the present disclosure. The components/hardware described herein are configured for use with a method for allowing an AC battery system (or portable battery station) to characterize and update maximum hysteresis polarization voltage during a life span of an AC battery system (e.g., the AC battery system 200). For example, once a maximum hysteresis polarization voltage is obtained, the AC battery system (e.g., the control system module 214) is configured to update a hysteresis value for improved estimation of one or more battery parameters. For example, a dynamic maximum hysteresis polarization voltage can be represented by M_{(z)} where M is a maximum polarization and Z is a SOC. FIG. 3 below shows an existence of hysteresis polarization. For example, the top trace represents charging open circuit voltage (OCV) and the bottom trace represents discharging OCV. When the AC battery system operates at idle for a relatively long time (e.g., >one hr), a diffusion voltage returns to 0. A hysteresis voltage value, however, remains constant. The voltage's maximum polarization can be characterized by configuring the AC battery system 200 to charge and discharge at a low current state and measure the changes of voltage during charging and discharging. The change in voltage that is measured during charging and discharging is the hysteresis maximum polarization. Due to the low current, the SOC is not changed during charging and discharging. In at least some embodiments, the AC battery system can characterize a maximum hysteresis polarization voltage without having to stay idle for a relatively long time. For example, as the diffusion voltage can be modelled through an R-C type of circuit, the diffusion voltage can be extracted from measured results on voltage, thus allowing the AC battery system to conduct characterization shortly after the AC battery system enter an idle mode. To accurately characterize the hysteresis maximum polarization value, the time duration for low current operation needs to allow cells to reach the maximum polarization. The time duration can be predetermined through empirical testing.

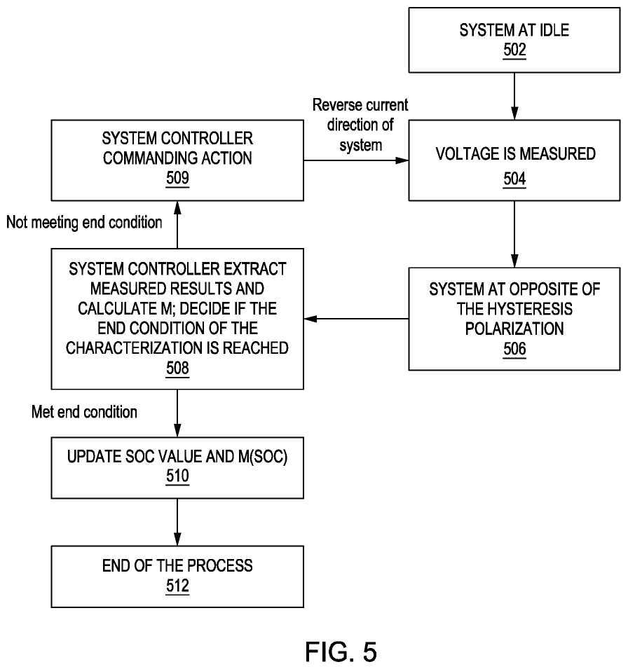

FIG. 4 is a graph of voltage vs state-of-charge, and FIG. 5 is a flowchart of a method 500 of operating AC battery systems, in accordance with at least some embodiments of the present disclosure. Initially, at 502, the method 500 can comprise placing the AC battery system 200 in idle (e.g., >one hour).

Next, at 504, the method 500 comprises measuring an initial voltage during a first predetermined state (e.g., a charging state) at a predetermined state-of-charge percentage. For example, in at least some embodiments, an initial voltage can be measured at 40% of SOC (0.40 SOC in faction), e.g., a starting point can be shortly after charging begins (see FIG. 4), to calculate the hysteresis maximum polarization value. A similar process to calculate hysteresis maximum polarization value can be obtained at an end of a discharging process. Continuing with reference to FIG. 4, V(_{Z=40%}) is measured and offset with diffusion voltage based on calculation, as described above.

Next, at 506, the method 500 comprises performing a discharging process. For example, the control system module 214 of the AC battery system 200 can start a discharging process by turning on all switching devices with only reactive power which is effectively very low C discharge. As illustrated in FIG. 4, the arrow pointing down represents a first attempt to reverse the polarization.

Next, at 508, the method 500 comprises measuring a subsequent voltage during a second predetermined state (e.g., a discharging state) different from the first predetermined state. For example, 508 can comprise calculating a new hysteresis maximum polarization value based on a difference between the initial voltage and the subsequent voltage. In at least some embodiments, 508 can comprise calculating a diffusion voltage and deducting a calculated diffusion voltage from the subsequent voltage. For example, the control system module 214 can calculate the hysteresis maximum polarization value based on measured voltage results, with the diffusion voltage being deducted. The control system module 214 measures voltage during the discharging process and calculates a difference between the voltage (e.g., the initial voltage) during charging and the voltage during discharging. In at least some embodiments, all battery cell voltages can be measured as well as battery pack voltages. The measured voltages can be used to determine each cell's hysteresis and pack level hysteresis value. If the SOC calculation later is based on battery pack level total voltage, the measured battery pack voltage is used; otherwise, individual battery cell level hysteresis can be used for battery cell level SOC and SOH calculations. SOC and SOH can be updated (e.g., using conventional methods that include the new hysteresis values determined by previous measurement and evaluation). The hysteresis value is a function of SOC and SOH, so at 508 the hysteresis value is updated to new SOC value and SOH. (e.g., in response to SOC and SOH update). Because the discharge rate is relatively low, the SOC value is considered to be unchanged, and temperature rise on cells can be ignored.

At 508, in at least some embodiments, the method 500 comprises calculating a final M_{(z)} value (the hysteresis maximum polarization value) based on a difference between an average of initial voltage measurements and an average of subsequent voltage measurements. For example, the control system module 214 of the AC battery system can calculate a final M_{(z)} value (the hysteresis maximum polarization value) based on an average of measured voltage values of all cells in the AC battery system, e.g., 24 values can be averaged. Alternatively, at 508, the control system module 214 of the AC battery system can be configured to use an individual cell's final M_{(z)} value.

Next, at 510, the method 500 comprises replacing (updating) a previously stored hysteresis maximum polarization value with the new hysteresis maximum polarization value for performing at least one of a state-of-charge analysis or a state-of-health analysis. For example, the control system module 214 can replace/update the SOC value and the final M_{(z)} for calculating a SOC or a SOH of the battery 120. In at least some embodiments, a reverse of the hysteresis maximum polarization value can be obtained by performing a charging process at low C, e.g., to obtain a repeatable data.

If at 508 a calculated hysteresis maximum polarization value does not meet certain criteria, at 509 the control system module 214 can repeat the process, e.g., in a reverse direction. For example, at 504 the initial voltage can be measured at 50% of SOC (0.50 SOC in faction), e.g., a starting point can be shortly after discharging begins, and at 506 performing a charging process (see FIG. 4), e.g., if the AC battery system just completed a charging process, the previous stated process can be reversed. As a result, regardless of if a previous state was at the end of discharging or charging, the method 500 can be used to update hysteresis.

In at least some embodiments, a correction step can be performed, as the previously estimated SOC is based on old hysteresis maximum polarization value assumptions. Therefore, a recalculation of Z can be performed based on a new M(z). The calculated new M_{(z)} value can be used to replace the old M_{(z)}. For instance, M_{(Z=37%)} after M re-calculation iterations are performed.

While the foregoing is directed to embodiments of the present disclosure, other and further embodiments of the disclosure may be devised without departing from the basic scope thereof, and the scope thereof is determined by the claims that follow.

1. An AC battery system configured for use with an energy management system, comprising:
a controller configured to measure an initial voltage during a first predetermined state at a predetermined state-of-charge percentage, measure a subsequent voltage during a second predetermined state different from the first predetermined state, calculate a new hysteresis maximum polarization value based on a difference between the initial voltage and the subsequent voltage, and replace a previously stored hysteresis maximum polarization value with the new hysteresis maximum polarization value for performing at least one of a state-of-charge analysis or a state-of-health analysis.

2. The AC battery system of claim 1, wherein the first predetermined state is a charging state of a battery of the AC battery system, and wherein the second predetermined state is a discharging state of the battery of the AC battery system.

3. The AC battery system of claim 1, wherein the controller is further configured to calculate the new hysteresis maximum polarization value based on a difference between an average of initial voltage measurements and an average of subsequent voltage measurements.

4. The AC battery system of claim 1, wherein the controller is further configured to calculate a diffusion voltage and deduct a calculated diffusion voltage from the subsequent voltage.

5. A method of operating an AC battery system configured for use with an energy management system, comprising:
measuring an initial voltage during a first predetermined state at a predetermined state-of-charge percentage;
measuring a subsequent voltage during a second predetermined state different from the first predetermined state;
calculating a new hysteresis maximum polarization value based on a difference between the initial voltage and the subsequent voltage; and
replacing a previously stored hysteresis maximum polarization value with the new hysteresis maximum polarization value for performing at least one of a state-of-charge analysis or a state-of-health analysis.

6. The method of claim 5, wherein the first predetermined state is a charging state of a battery of the AC battery system, and wherein the second predetermined state is a discharging state of the battery of the AC battery system.

7. The method of claim 5, further comprising calculating the new hysteresis maximum polarization value based on a difference between an average of initial voltage measurements and an average of subsequent voltage measurements.

8. The method of claim 5, further comprising calculating a diffusion voltage and deducting a calculated diffusion voltage from the subsequent voltage.

9. A non-transitory computer readable storage medium having instructions stored thereon that when executed by a processor perform a method of operating an AC battery system configured for use with an energy management system, comprising:
measuring an initial voltage during a first predetermined state at a predetermined state-of-charge percentage;
measuring a subsequent voltage during a second predetermined state different from the first predetermined state;
calculating a new hysteresis maximum polarization value based on a difference between the initial voltage and the subsequent voltage; and
replacing a previously stored hysteresis maximum polarization value with the new hysteresis maximum polarization value for performing at least one of a state-of-charge analysis or a state-of-health analysis.

10. The non-transitory computer readable storage medium of claim 9, wherein the first predetermined state is a charging state of a battery of the AC battery system, and wherein the second predetermined state is a discharging state of the battery of the AC battery system.

11. The non-transitory computer readable storage medium of claim 9, further comprising calculating the new hysteresis maximum polarization value based on a difference between an average of initial voltage measurements and an average of subsequent voltage measurements.

12. The non-transitory computer readable storage medium of claim 9, further comprising calculating a diffusion voltage and deducting a calculated diffusion voltage from the subsequent voltage.
